(19) United States
(12) Patent Application Publication
(10) Pub. No.: US 2008/0111587 A1
(43) Pub. Date: May 15, 2008

(54) INPUT RECEIVER WITH NEGATIVE VOLTAGE GENERATOR AND RELATED METHOD

(76) Inventor: Wei-Li Liu, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/759,223

(22) Filed: Jun. 6, 2007

(30) Foreign Application Priority Data
Nov. 13, 2006 (TW) 095141917

(51) Int. Cl. H03B 1/00; H03F 3/45

(52) U.S. Cl. 327/108; 330/253

(57) ABSTRACT

An input receiver includes a negative voltage generator and an amplifier for amplifying an input signal. The negative voltage generator generates a negative voltage. The amplifier is coupled to the input signal, a supply voltage, and the negative voltage, and amplifies the input signal to generate an amplified signal accordingly.

### BACKGROUND OF THE INVENTION

1. Field of the Invention

The present invention relates to an input receiver, and more particularly, to an input receiver with a negative voltage generator.

2. Description of the Prior Art

Typical semiconductor electronic devices include input receivers that utilize amplifiers to amplify single-sided or differential input signals to generate single-sided or differential amplified signals. FIG. 1 is a schematic diagram of a conventional input receiver 100. The input receiver 100 is a differential amplifier including five transistors M1-M5. The transistors M1, M2, M3 and M4 are utilized for amplifying an input signal Vin to generate an amplified signal Vamp, and the transistor M5 provides a bias current that the input receiver requires in operation according to a bias voltage. In addition, one end of the input receiver 100 is coupled to a supply voltage VDD, and another end is coupled to ground so that the input receiver 100 can have electric power required in operation.

With miniaturization of semiconductor technology, various semiconductor devices are experiencing two trends: increased operation speed and reduced supply voltage. To deal with these two trends, circuit elements in the semiconductor electronic devices must possess good characteristics so that the semiconductor devices can achieve the performance required in operation. However, it is not a simple task to make the circuit elements in the semiconductor electronic devices possess good characteristics and maintain sufficient reliability at the same time.

Take the input receiver 100 shown in FIG. 1 for example. First, suppose Vref is equal to 0.5 VDD, and the DC component of Vin is also equal to 0.5 VDD. If VDD is equal to 2.5V, then both the DC components of Vref and Vin are equal to 1.25V. In this situation, the gate-source voltage Vgs1 of the transistor M1 will be higher than the threshold voltage of the transistor M1, so the transistor M1 can operate regularly in the saturation region (Vgs>Vth). Similarly, the gate-source voltage Vgs2 of the transistor M2 is also higher than the threshold voltage, so the transistor M2 can also operate regularly in the saturation region. When both of the transistors M1, M2 operate in the saturation region, the input receiver 100 will operate regularly.

However, as the frequency of the input signal Vin increases, and the supply voltage VDD decreases, the transistors M1 and M2 may not operate in the saturation region. That is, the input receiver 100 cannot operate regularly. For example, when VDD is 1.8V, the DC components of Vref and Vin are 0.9V. In this case, the gate-source voltage Vgs1 of the transistor M1 will be closer to the threshold voltage of the transistor M1, so the transistor M1 may operate in the linear region for some inputs, and not in the saturation region. Likewise, the gate-source voltage Vgs2 of the transistor M2 will also be closer to the threshold voltage of the transistor M2, so the transistor M2 may operate in the linear region, and not in the saturation region. Therefore, the input receiver 100 cannot operate regularly.

### SUMMARY OF THE INVENTION

Therefore one of the objectives of the present invention is to provide an input receiver and related method having higher reliability in order to solve the above-mentioned problems.

According to the present invention, an input receiver is disclosed. The input receiver comprises a negative voltage generator and an amplifier coupled to the negative voltage generator. The negative voltage generator generates a negative voltage. The amplifier is coupled to an input signal, a supply voltage and the negative voltage, and amplifies the input signal to generate an amplified signal accordingly.

According to the present invention, a method for amplifying an input signal is disclosed. The method comprises providing a supply voltage and a negative voltage to an amplifier and utilizing the amplifier to amplify the input signal to generate an amplified signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an input receiver according to the prior art.

FIG. 2 is a schematic diagram of an input receiver according to an embodiment of the present invention.

FIG. 3 is an example of a circuit diagram of the input receiver shown in FIG. 2.

### DETAILED DESCRIPTION

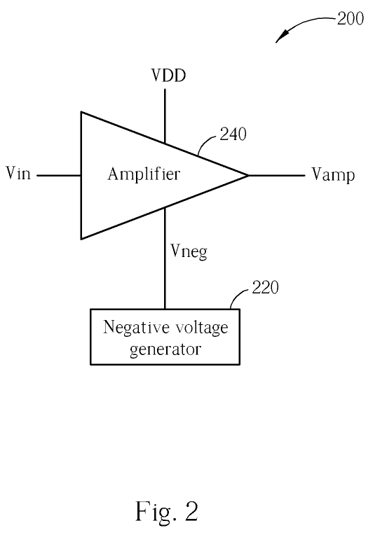

FIG. 2 is a schematic diagram of an input receiver according to an embodiment of the present invention. In this embodiment, the input receiver 200 comprises a negative voltage generator 220 and an amplifier 240. The negative voltage generator 220 is utilized for generating a negative voltage Vneg lower than ground voltage. The amplifier 240 is utilized for amplifying an input signal Vin to generate an amplified signal Vamp. In addition, one end of the amplifier 240 is coupled to a supply voltage VDD, and another end of the amplifier 240 is coupled to the negative voltage generator 220 to receive the negative voltage Vneg, so that the amplifier 240 can have the electric power required in operation. The input signal Vin can be a single-ended signal or a differential signal, and the amplified signal Vamp also can be a single-ended signal or a differential signal.

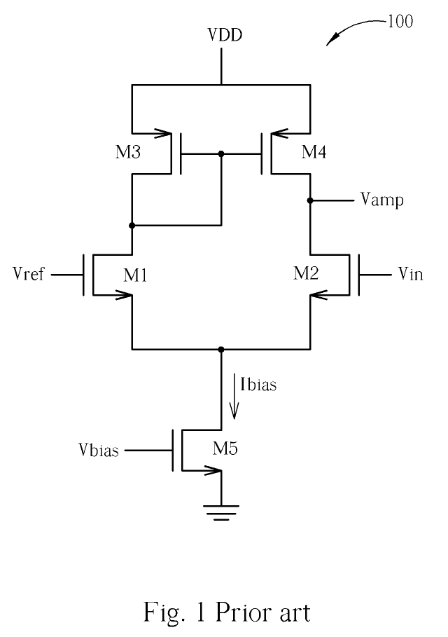

One of the purposes of utilizing the negative voltage generator 220 is for increasing an effective supply voltage of the amplifier 240 according to the negative voltage Vneg generated by the negative voltage generator 220. Take the conventional input receiver 100 shown in FIG. 1 for example. Because one end of the conventional input receiver 100 is coupled to the supply voltage VDD, and another end is coupled to ground (the voltage of the ground Vground=0), the effective supply voltage of the conventional input receiver 100 is VDD−Vground=VDD−0=VDD. Conversely, because one end of the amplifier 240 shown in FIG. 2 is coupled to the supply voltage VDD, and another end is coupled to negative voltage Vneg, the effective supply voltage of the amplifier 240 is VDD−Vneg. Because the negative voltage Vneg is less than zero, the effective supply voltage of the amplifier 240 will be higher than the supply voltage VDD.

Because the existence of the negative voltage Vneg increases the effective supply voltage of the amplifier 240, it can easily ensure that the circuit elements in the amplifier 240 operate in a desirable operation region, such as the saturation region. Therefore, even if the supply voltage VDD is lower, the input receiver 200 can still operate regularly.

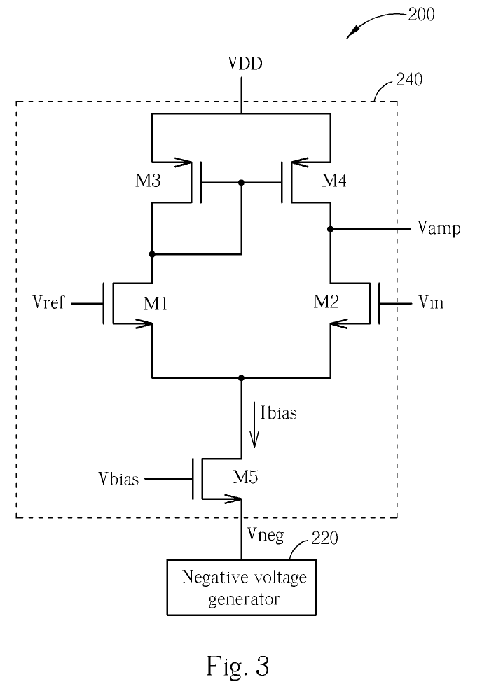

FIG. 3 is an example of a circuit diagram of the input receiver 200. In this example, the amplifier 240 comprises five transistors M1-M5, wherein the transistors M1, M2, M3 and M4 amplify an input signal Vin to generate an amplified signal Vamp accordingly, and the transistor M5 supplies a bias current required by the amplifier 240 in operation according to a bias voltage. Because the drain of the transistor M5 is not coupled to ground voltage but to the negative voltage Vneg, which is lower than the ground voltage, the gate-source voltages of the transistors M1, M2 can be increased, such that the transistors M1, M2 can operate in the saturation region. Therefore, even if the value of the supply voltage VDD is lower, the input receiver 200 still can operate regularly.

It should be noted that the circuit diagram shown in FIG. 3 is a simplified example of the input receiver 200. Actually, the amplifier 240 can be any amplifier, including a single-ended input single-ended output (SISO) amplifier, a single-ended input differential output (SIDO) amplifier, a differential input single ended output (DISO) amplifier, or a differential input differential output (DIDO) amplifier.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An input receiver, comprising:
a negative voltage generator for generating a negative voltage; and an amplifier coupled to an input signal, a supply voltage and the negative voltage generator for amplifying the input signal to generate an amplified signal.

2. The input receiver of claim 1, wherein the negative voltage is lower than a ground voltage.

3. The input receiver of claim 1, wherein an effective supply voltage of the amplifier is higher than the supply voltage.

4. The input receiver of claim 1, wherein an effective supply voltage of the amplifier is equal to the supply voltage minus the negative voltage.

5. The input receiver of claim 1, wherein the amplifier is a single-ended input single-ended output amplifier.

6. The input receiver of claim 1, wherein the amplifier is a single-ended input differential output amplifier.

7. The input receiver of claim 1, wherein the amplifier is a differential input single-ended output amplifier.

8. The input receiver of claim 1, wherein the amplifier is a differential input differential output amplifier.

9. A method of amplifying an input signal, comprising:
providing a supply voltage and a negative voltage to an amplifier; and
utilizing the amplifier for amplifying the input signal to generate an amplified signal.

10. The method of claim 9, further comprising:
utilizing a negative voltage generator to generate the negative voltage.

11. The method of claim 9, wherein the negative voltage is lower than a ground voltage.

12. The method of claim 9, wherein an effective supply voltage of the amplifier is higher than the supply voltage.

13. The method of claim 9, wherein an effective supply voltage of the amplifier is equal to the supply voltage minus the negative voltage.

14. The method of claim 9, wherein the amplifier is a single-ended input single-ended output amplifier.

15. The method of claim 9, wherein the amplifier is a single-ended input differential output amplifier.

16. The method of claim 9, wherein the amplifier is a differential input single-ended output amplifier.

17. The method of claim 9, wherein the amplifier is a differential input differential output amplifier.
